(19) United States
(12) Patent Application Publication
(10) Pub. No.: US 2024/0224697 A1
(43) Pub. Date: Jul. 4, 2024

(54) DISPLAY DEVICE

(71) Applicant: LG Display Co., Ltd., Seoul (KR)

(72) Inventors: SeongHan HWANG, Goyang-si (KR); ByungGwan HYUN, Bucheon-si (KR); KyungKook JANG, Goyang-si (KR); YoonJung EO, Paju-si (KR)

(73) Assignee: LG Display Co., Ltd., Seoul (KR)

(21) Appl. No.: 18/523,541

(22) Filed: Nov. 29, 2023

(30) Foreign Application Priority Data
Dec. 30, 2022 (KR) 10-2022-0190451

(51) Int. Cl. H10K 59/38; H10K 59/122; H10K 59/35; H10K 59/80

(52) U.S. Cl. CPC H10K 59/38; H10K 59/122; H10K 59/351; H10K 59/353; H10K 59/8792

(57) ABSTRACT

Discussed is a display device including a black matrix disposed on an encapsulation layer to correspond to a bank and including a plurality of openings overlapping emission areas respectively, and a plurality of color filters disposed on the encapsulation layer to correspond to a plurality of sub-pixels, respectively. Each of the plurality of color filters includes a first region overlapping a corresponding emission area and a second region adjacent the first region and having at least a portion disposed to cover at least a portion of an upper surface of the black matrix, and at least one of the plurality of color filters includes a plurality of holes in at least one of an edge of the first region and the second region.

### CROSS-REFERENCE TO RELATED APPLICATIONS

This application claims the benefit of and priority to Korean Patent Application No. 10-2022-0190451 filed on Dec. 30, 2022 in the Republic of Korea, the entire contents of which are hereby expressly incorporated by reference into the present application.

### BACKGROUND OF THE DISCLOSURE

### Field

The present disclosure relates to a display device, and more particularly, to a display device in which a luminance viewing angle and a color viewing angle are excellent and rainbow stain is prevented or reduced based on a plurality of holes provided in a color filter.

### Discussion of the Related Art

In general, an organic light emitting display device includes an anode, a cathode, and an organic light emitting layer disposed therebetween. As the cathode is formed using a metallic material having high reflectivity, external light is reflected by the metallic material, thereby causing a disadvantage such as a decrease in contrast ratio or reflective visibility. Accordingly, a polarizing plate for absorbing external light can be disposed below a cover member in order to reduce reflection of external light. The polarizing plate generally is a film having a certain level of light transmittance and absorbing external light and its reflected light to thereby prevent or reduce a decrease in contrast ratio.

Recently, as interest in flexible and slim display devices has increased, display devices using a relatively thin coated polarizing film instead of a thick polarizing plate have been proposed. However, even the coated polarizing film is also thick and not sufficiently thin to be used in a foldable display, and yet, when the thickness of the polarizing film is reduced, functions and display quality of the polarizing film are degraded as there is a point when the polarizing film is too thin to be functional.

Accordingly, a color filter on encapsulation layer (CoE) structure has been proposed instead of using a polarizing plate or a coated polarizing film. A conventional CoE structure is a structure in which a black matrix is disposed on an encapsulation layer to correspond to a non-emission area and a color filter is disposed to correspond to an emission area. The conventional CoE structure can reduce a thickness of a display device and at the same time, improve display quality by absorbing external light and reflected light without reducing luminous efficiency. However, since directions of light emitted in the front are identical regardless of positions in the conventional CoE structure, there still can be in which a luminance viewing angle is reduced and color shift occurs.

### SUMMARY OF THE DISCLOSURE

In order to solve or address the defects or disadvantages associated with conventional CoE structures, a pull-back structure is applied in which a width of the color filter is formed to be greater than that of an emission area corresponding thereto. However, when the pull-back structure is applied, a width of banks is greater than that of a black matrix, so that the banks are exposed without being completely covered by the black matrix. Accordingly, there can be a limitation in which display quality is degraded by occurrence of rainbow stain due to the banks exposed.

Accordingly, an aspect of the present disclosure is to provide a display device in which a luminance viewing angle and a color viewing angle are excellent or improved by changing an emission direction of light at each position.

Another aspect of the present disclosure is to provide a display device in which rainbow stain is prevented or reduced and a luminance viewing angle and a color viewing angle are excellent or improved even if a pull-back structure is applied.

Still another aspect of the present disclosure is to provide a display device having excellent or improved display quality by fundamentally eliminating a rainbow stain phenomenon, while having an excellent or improved luminance viewing angle and color viewing angle by shifting light emitted in a front direction to a viewing angle direction without applying a pull-back structure.

Still another aspect of the present disclosure is to allow for slimming of a display device and easily implement the display device in various shapes such as a curved shape or a foldable shape.

Still another aspect of the present disclosure is to provide a display device with improved display quality by absorbing external and reflected light while having excellent or improved luminous efficiency.

Objects of the present disclosure are not limited to the above-mentioned objects, and other objects, which are not mentioned above, can be clearly understood by those skilled in the art from the following descriptions.

A display device according to an example embodiment of the present disclosure includes a substrate on which a plurality of sub-pixels are defined; an anode disposed on the substrate to correspond to each of the plurality of sub-pixels; an organic light emitting layer disposed on the anode; a cathode disposed on the organic light emitting layer; a bank disposed to cover an edge of the anode to define a plurality of emission areas; an encapsulation layer disposed on the cathode; a black matrix disposed on the encapsulation layer to correspond to the bank and including a plurality of openings overlapping the plurality of emission areas respectively; and a plurality of color filters disposed on the encapsulation layer to correspond to the plurality of sub-pixels respectively, wherein each of the plurality of color filters includes a first region overlapping the emission area and a second region surrounding the first region and having at least a portion disposed to cover at least a portion of an upper surface of the black matrix, and includes a plurality of holes in at least one of an edge of the first region and the second region.

Other detailed matters of the example embodiments are included in the detailed description and the drawings.

The display device according to the present disclosure has advantages in which holes are formed in a specific region of a color filter, so that light emitted in a front direction is shifted in a viewing angle direction, thereby leading to an excellent or improved luminance viewing angle and an excellent or improved color viewing angle.

According to the present disclosure, it is possible to provide a display device having excellent or improved display quality by improving a luminance viewing angle and a color viewing angle even without applying a pull-back structure.

According to the present disclosure, even if a pull-back structure is applied, emitted light is totally reflected by holes provided in a color filter to provide an effect of preventing rainbow stain.

According to the present disclosure, it is possible to provide a display device allowing for an improvement in reflective visibility and a reduction in an overall thickness of the display device by including a black matrix and color filters that function as anti-reflection elements instead of a polarizer, and it is possible to provide a display device capable of being easily implemented in various shapes such as a curved shape or a foldable shape.

The effects according to the present disclosure are not limited to the contents exemplified above, and more various effects are included in the present specification.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a plan view of a display device according to an example embodiment of the present disclosure.

FIG. 2 is an enlarged plan view of one pixel of a display device according to an example embodiment of the present disclosure.

FIG. 3 is a cross-sectional view taken along I-I′ of FIG. 2.

FIG. 4 is a view illustrating an angle at which light is emitted in each location in the display device according to an example embodiment of the present disclosure.

FIG. 5 is a view for explaining a structure in which a hole has a line shape in another example embodiment of the present disclosure.

FIG. 6 is an enlarged plan view of one pixel of a display device according to another example embodiment of the present disclosure.

FIG. 7 is a cross-sectional view taken along II-II′ of FIG. 6.

FIG. 8 is an enlarged plan view of one pixel of a display device according to still another example embodiment of the present disclosure.

FIG. 9 is a cross-sectional view taken along III-III′ of FIG. 8.

FIG. 10 is an enlarged plan view of one pixel of a display device according to still another example embodiment of the present disclosure.

FIG. 11 is a cross-sectional view taken along IV-IV′ of FIG. 10.

FIG. 12 is an enlarged plan view of one pixel of a display device according to still another example embodiment of the present disclosure.

FIG. 13 is a cross-sectional view taken along V-V′ of FIG. 12.

FIG. 14 is an enlarged plan view of one pixel of a display device according to still another example embodiment of the present disclosure.

FIG. 15 is a cross-sectional view taken along VI-VI′ of FIG. 14.

FIG. 16 is a schematic cross-sectional view of a display device according to still another example embodiment of the present disclosure.

FIG. 17 is a graph illustrating luminance distribution according to viewing angles of specimens according to Examples of the present disclosure and Comparative Example.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define any order or sequence. Therefore, a first component to be mentioned below can be a second component in a technical concept of the present disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operationally coupled and configured.

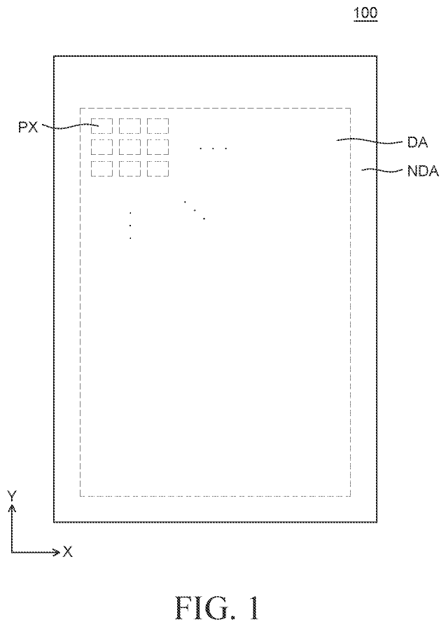

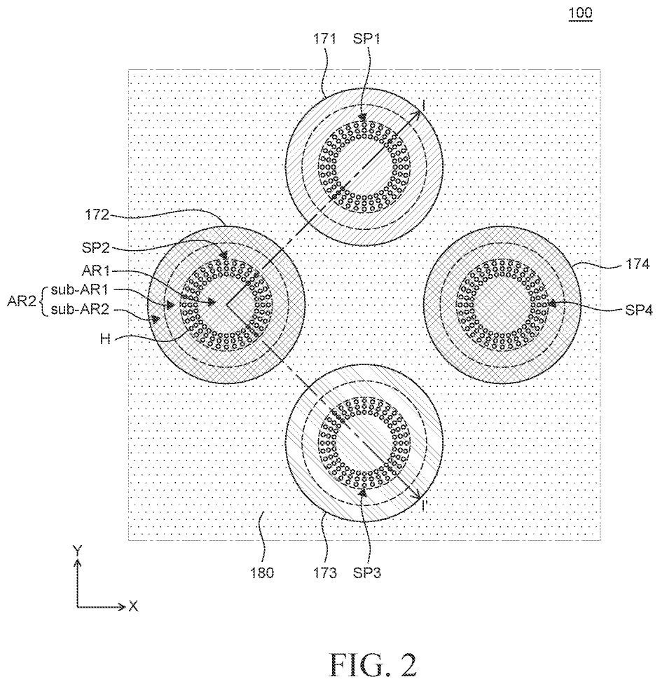

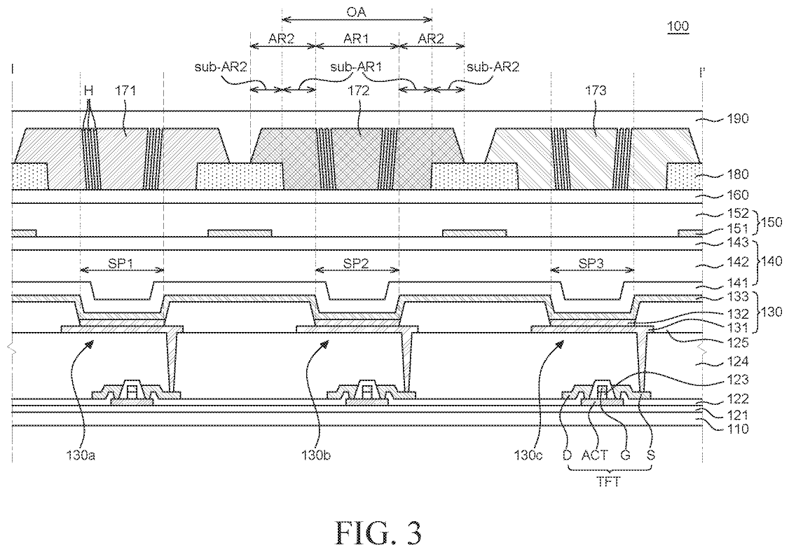

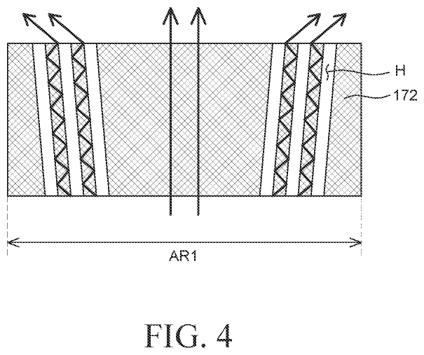

FIG. 1 is a plan view of a display device according to an example embodiment of the present disclosure. FIG. 2 is an enlarged plan view of one pixel of a display device according to an example embodiment of the present disclosure. FIG. 3 is a cross-sectional view taken along I-I′ of FIG. 2. FIG. 4 is a view illustrating an angle at which light is emitted in each location in the display device according to an example embodiment of the present disclosure.

Referring to FIGS. 1 to 4, a display device 100 according to an example embodiment of the present disclosure includes a substrate 110, thin film transistors TFT, organic light emitting elements 130, an encapsulation layer 140, and a touch sensor unit 150, a plurality of color filters 171, 172, 173, and 174, and a black matrix 180.

The display device 100 according to an example embodiment of the present disclosure includes areas defined as a display area DA and a non-display area NDA. The display area DA is an area where a plurality of pixels PX are disposed to substantially display an image. The pixels PX including emission areas for displaying an image and driving circuits for driving the pixels PX can be disposed in the display area DA. The non-display area NDA surrounds the display area DA. The non-display area NDA is an area in which an image is not substantially displayed, and various lines, driver ICs, printed circuit boards, and the like for driving the pixels PX and driving circuits disposed in the display area DA can be disposed in the non-display area NDA.

The plurality of pixels PX are arranged in a matrix shape, and each of the plurality of pixels PX can include a plurality of sub-pixels, such as SP1, SP2, SP3, and SP4. The sub-pixels SP1, SP2, SP3, and SP4 are elements for displaying one color, respectively, and include emission areas in which light is emitted and non-emission areas in which light is not emitted. In this specification, only the emission area in which light is emitted is defined as the sub-pixel. For example, each of the plurality of sub-pixels can display any one color among red, green, and blue, but the present disclosure is not limited thereto. Thus, each of the plurality of sub-pixels can display other colors other than red, green and blue.

For example, one pixel PX can include a first sub-pixel SP1, a second sub-pixel SP2, a third sub-pixel SP3, and a fourth sub-pixel SP4. For example, the second sub-pixel SP2 and the fourth sub-pixel SP4 can be alternately arranged in a first direction (an X-axis direction), and the first sub-pixel SP1 and the third sub-pixel SP3 can be alternately arranged in a second direction (a Y-axis direction) between the second sub-pixel SP2 and the fourth sub-pixel SP4. However, the present disclosure is not limited thereto. The first sub-pixel SP1 and the third sub-pixel SP3 can be arranged in a zigzag manner with the second sub-pixel SP2 and the fourth sub-pixel SP4, but the present disclosure is not limited thereto.

The first sub-pixel SP1, the second sub-pixel SP2, the third sub-pixel SP3, and the fourth sub-pixel SP4 can display different colors, and some of the sub-pixels can display the same color as needed. For example, the first sub-pixel SP1 can be a red sub-pixel, each of the second sub-pixel SP2 and the fourth sub-pixel SP4 can be a green sub-pixel, and the third sub-pixel SP3 can be a blue sub-pixel. However, the present disclosure is not limited thereto, and other colors can be used.

In the drawings, sizes of the respective sub-pixels SP1, SP2, SP3, and SP4 are illustrated to be equal, but areas of the respective sub-pixels SP1, SP2, SP3, and SP4 can be differently formed for respective colors displayed by the sub-pixels SP1, SP2, SP3 and SP4 in consideration of luminance and color temperature. For example, the blue third sub-pixel SP3 can have a larger area than those of the first sub-pixel SP1, the second sub-pixel SP2, and the fourth sub-pixel SP4. The second sub-pixel SP2 and the fourth sub-pixel SP4 that are green sub-pixels can have a larger area than the first sub-pixel SP1 that is a red sub-pixel, but the present disclosure is not limited thereto.

Each of the sub-pixels SP1, SP2, SP3, and SP4 can have, but is not particularly limited to, a circular shape, an elliptical shape, or a polygonal shape such as a triangular shape, a quadrangular shape, a pentagonal shape, or a hexagonal shape.

The substrate 110 is a substrate for supporting various elements constituting the display device. For example, the substrate 110 can be a plastic substrate. For example, the plastic substrate can be selected from among polyimide, polyethersulfone, polyethylene terephthalate, and polycarbonate, but the present disclosure is not limited thereto, and a non-plastic material can be used, such as a metal, metal alloy or other composite materials. In the example of using a plastic substrate having flexibility, a support member such as a back plate can be disposed under the substrate 110. Since a plastic substrate having flexibility is relatively thin and less in rigidity compared to a glass substrate, sagging thereof can occur when various elements are disposed. The back plate can support the substrate 110 formed of plastic so that sagging of the substrate 110 does not occur, and protect the display device 100 from moisture, heat, impacts, and the like. For example, the back plate can be formed of a metallic material or an alloy such as stainless steel (SUS), or can be formed of a plastic material such as polymethylmethacrylate, polycarbonate, polyvinyl alcohol, acrylonitrile-butadiene-styrene, or polyethylene terephthalate. Other rigid material can be used for the back plate. When the back plate is disposed under the substrate 110, an adhesive layer can be disposed between the substrate 110 and the back plate to bond them together. The adhesive layer can be an optical transparent adhesive or a pressure sensitive adhesive, but the present disclosure is not limited thereto.

A substrate buffer layer 121 can be disposed on the substrate 110 to prevent penetration of oxygen or moisture. The substrate buffer layer 121 can be formed as a single layer or can be formed as a multilayer structure if necessary. The thin film transistor TFT including a gate electrode G, an active layer ACT, a source electrode S, and a drain electrode D is disposed on the substrate buffer layer 121. The thin film transistor TFT is disposed for each area of the first sub-pixel SP1, the second sub-pixel SP2, the third sub-pixel SP3, and the fourth sub-pixel SP4. In the drawings, only a driving thin film transistor among various thin film transistors that can be included in the display device 100 is illustrated for convenience of description. Further, in the drawings, it is by example illustrated that the thin film transistor TFT has a coplanar structure, but the present disclosure is not limited thereto, and a thin film transistor TFT having an inverted staggered structure can also be used. For example, the active layer ACT is disposed on the substrate buffer layer 121, and a gate insulating layer 123 for insulating the active layer ACT and the gate electrode G can be disposed on the active layer ACT. In addition, an interlayer insulating layer 122 can be disposed on the substrate buffer layer 121 to insulate the gate electrode G, and the source electrode S and the drain electrode D. The source electrode S and the drain electrode D that are respectively in contact with the active layer ACT are formed on the interlayer insulating layer 122. A planarization layer 124 can be disposed on the thin film transistor TFT. The planarization layer 124 planarizes an upper portion of the thin film transistor TFT. The planarization layer 124 can include contact holes for electrically connecting the thin film transistors TFT and anodes 131 of the organic light emitting elements 130.

The organic light emitting elements 130 are disposed on the planarization layer 124. The organic light emitting elements 130 are respectively disposed in each of the plurality of sub-pixel regions SP1, SP2, SP3, and SP4. The organic light emitting elements 130 include a first organic light emitting element 130a disposed in the first sub-pixel SP1, a second organic light emitting element 130b disposed in the second sub-pixel SP2, and a third organic light emitting element 130c disposed in the third sub-pixel SP3. Each of the organic light emitting elements 130a, 130b, and 130c includes the anode 131, an organic light emitting layer 132, and a cathode 133.

The anode 131 is disposed on planarization layer 124. The anode 131 is disposed to correspond to each of the plurality of sub-pixels SP1, SP2, SP3, and SP4. The anode 131 is a component for supplying holes to the organic light emitting layer 132 and can be formed of or include a conductive material having a high work function. The anode 131 can be a transparent conductive layer formed of transparent conductive oxide (TCO). For example, the anode 131 can be formed of or include at least one selected from among transparent conductive oxides such as indium-tin-oxide (ITO), indium-zinc-oxide (IZO), indium-tin-zinc-oxide (ITZO), tin oxide (SnO₂), zinc oxide (ZnO), indium-copper-oxide (ICO) and aluminum-doped ZnO (AZO), but the present disclosure is not limited thereto. Other conductive oxides, or other materials can be used. When the display device 100 is driven in a top emission mode, the anode 131 can further include a reflective layer to reflect light emitted from the organic light emitting layer 132 toward the cathode 133. The anodes 131 can be formed separately for each of the first sub-pixel SP1, the second sub-pixel SP2, and the third sub-pixel SP3. Banks 125 are disposed on the anodes 131 and the planarization layer 124. The banks 125 can be disposed to cover edges of the anodes 131 of the organic light emitting elements 130. For example, the banks 125 can cover the edges of the anodes 131 to define emission areas for the respective sub-pixels. The banks 125 can partition the plurality of sub-pixels SP1, SP2, SP3, and SP4. The banks 125 can be formed of an insulating material to insulate the anodes 131 of the sub-pixels SP1, SP2, and SP3 adjacent to one another. In addition, the banks 125 can be configured as black banks having a high light absorption rate to prevent or reduce color mixing between the adjacent sub-pixels SP1, SP2, and SP3. For example, the banks 125 can be formed of polyimide resin, acrylic resin, or benzocyclobutene resin, but the present disclosure is not limited thereto.

The cathode 133 is disposed on the anode 131. The cathode 133 can be formed of a metallic material having a low work function to smoothly supply electrons to the organic light emitting layer 132. For example, the cathode 133 can be formed of a metallic material selected from among calcium (Ca), barium (Ba), aluminum (Al), silver (Ag), and alloys containing one or more of them, but the present disclosure is not limited thereto. Other metals, or other materials, such as conductive oxides can also be used for the cathode 133. The cathode 133 can be formed as one layer on the anode 131. For example, the cathode 133 can be formed as a single layer or a common layer in the first sub-pixel SP1, the second sub-pixel SP2, the third sub-pixel SP3, and the fourth sub-pixel SP4. When the display device 100 is driven in the top emission mode, the cathode 133 can be formed to have a very thin thickness and can be substantially transparent, for example, when using the metallic materials.

The organic light emitting layer 132 is disposed between the anode 131 and the cathode 133. The organic light emitting layer 132 is a layer that emits light by combining electrons and holes. For example, the organic light emitting layer 132 can be separately provided for each of a plurality of sub-pixels SP1, SP2, SP3, and SP4. In this example, the organic light emitting layer 132 is configured to emit light of the same color as the corresponding sub-pixel. For example, the organic light emitting layer of the first organic light emitting element 130a can be a red organic light emitting layer, the organic light emitting layer of the second organic light emitting element 130b can be a green organic light emitting layer, and the organic light emitting layer of the third organic light emitting element 130c can be a blue organic light emitting layer. However, the present disclosure is not limited thereto. As another example, the organic light emitting layer 132 can be provided as a common layer without being separated for each of the plurality of sub-pixels SP1, SP2, SP3, and SP4. In this example, the organic light emitting layer 132 can be configured to emit white light, and light having a color corresponding to each of the sub-pixels SP1, SP2, SP3, and SP4 can be emitted through the respective color filter 170 of different colors. The organic light emitting element 130 can further include a hole injection layer, a hole transport layer, an electron transport layer, an electron injection layer, and the like to improve luminous efficiency. Other layers can be included as needed to further improve characteristics. For example, the hole injection layer and the hole transport layer can be disposed between the anode 131 and the organic light emitting layer 132, and the electron transport layer and the electron injection layer can be disposed between the organic light emitting layer 132 and the cathode 133. In addition, a hole blocking layer or an electron blocking layer can be disposed in the organic light emitting layer 132 to further improve recombination efficiency of holes and electrons.

The encapsulation layer 140 can be disposed on the organic light emitting element 130. The encapsulation layer 140 can cover the organic light emitting element 130. The encapsulation layer 140 can protect the organic light emitting element 130 from external moisture, oxygen, impacts, and the like. The encapsulation layer 140 can have a multilayer structure in which an inorganic layer formed of an inorganic insulating material and an organic layer formed of an organic material are stacked. For example, the encapsulation layer 140 can be configured to include at least one organic layer and at least two inorganic layers, and can have a multilayer structure in which the inorganic layer and the organic layer are alternately stacked, but the present disclosure is not limited thereto. For example, the encapsulation layer 140 can have a triple-layer structure including a first inorganic layer 141, an organic layer 142, and a second inorganic layer 143, but additional layers and stackings can be used if desired. In this example, each of the first inorganic layer 141 and the second inorganic layer 143 can be independently formed of at least one selected from silicon nitride (SiNx), silicon oxide (SiOx), aluminum oxide (AlOx), and silicon oxynitride (SiON), but the present disclosure is not limited thereto, and other inorganic materials can be used. In addition, the organic layer 142 can be formed of at least one selected from epoxy resin, polyimide, polyethylene, and silicon oxycarbide (SiOC), but the present disclosure is not limited thereto, and other organic materials can be used.

The touch sensor unit 150 can be disposed on the encapsulation layer 140 in order to provide a touch sensing function to the display device 100. For example, the touch sensor unit 150 can be disposed in a Touch on Encapsulation (ToE) structure in which touch electrodes 151 are formed on the encapsulation layer 140. A touch panel in which touch electrodes are formed on a separate substrate can be disposed on an upper portion of the organic light emitting element through an adhesive member, but in this example, the thickness of the display device becomes thicker, and foldability of the display device can be reduced or deteriorated. When the touch sensor unit 150 is directly formed on the encapsulation layer 140 without an adhesive member according to an example embodiment of the present disclosure, a separate substrate for forming a touch electrode or an adhesive member for bonding the touch sensor unit can be omitted. Thus, the thickness of the display device 100 can be reduced, and the display device 100 can be easily implemented as a flexible display device.

The touch sensor unit 150 can include a plurality of the touch electrodes 151 and a touch protection layer 152. A touch buffer layer can be selectively disposed on the second inorganic layer 143 as needed, and the plurality of touch electrodes 151 can be disposed on the touch buffer layer. The touch buffer layer can be directly disposed on the second inorganic layer 143 to improve adhesion between the plurality of touch electrodes 151 and the second inorganic layer 143. The touch buffer layer can be disposed on an entire surface of the substrate 110 over the display area DA and the non-display area NDA. Accordingly, when forming the plurality of touch electrodes 151, the touch buffer layer can protect the organic light emitting elements 130 and signal lines or pads disposed in the non-display area NDA to drive the organic light emitting elements 130, from being damaged. The touch buffer layer can be formed of an inorganic insulating material, for example, can be formed of at least one selected from silicon nitride (SiNx), silicon oxide (SiOx), aluminum oxide (AlOx), and silicon oxynitride (SiON), but the present disclosure is not limited thereto, and other materials can be used.

The plurality of touch electrodes 151 can be layers including electrodes that sense a touch input. The plurality of touch electrodes 151 can be configured with a plurality of sensing electrodes and a plurality of driving electrodes, and can detect touch coordinates by detecting a change in capacitance between the electrodes. For example, the sensing electrodes and the driving electrodes can be disposed on the same plane, and at least some of the plurality of touch electrodes 151 can be electrically connected through a bridge electrode disposed on a plane different from that of the touch electrodes with an insulating layer interposed therebetween. However, the present disclosure is not limited thereto, and a configuration of the touch sensor unit 150 can be variously changed as needed.

Each of the plurality of touch electrodes 151 can be disposed to correspond to a boundary of the sub-pixels. In this example, efficiency of light emitted from the organic light emitting element 130 can be maintained high without being lowered, and display quality can be excellent or improved since the touch electrodes 151 are not visible from the outside. The touch electrodes 151 can be disposed on the encapsulation layer 140 to correspond to spaces between the color filters 171, 172, 173, and 174 adjacent to each other. For example, the touch electrodes 151 can be disposed on the encapsulation layer 140 to correspond to the black matrix 180. However, the present disclosure is not limited thereto, and an arrangement structure of the touch electrodes 151 can be changed as needed.

The touch electrodes 151 can be formed of a transparent metallic material or an oxide such as indium-tin-oxide (ITO) or indium-zinc-oxide (IZO) capable of transmitting light. The touch electrodes 151 can have various shapes such as a rectangular shape, an octagonal shape, a circular shape, or a rhombus shape, among others. The touch insulating layers 153 and 154 can be formed of an inorganic insulating material or an organic insulating material, and can have a multilayer structure in which a layer formed of an inorganic insulating material and a layer formed of an organic insulating material are alternately disposed.

For example, the touch protection layer 152 can be formed of at least one inorganic insulating material selected from among silicon nitride (SiNx), silicon oxide (SiOx), aluminum oxide (AlOx), and silicon oxynitride (SiON), or can be formed of a transparent organic insulating material such as acrylic resin, polyester-based resin, epoxy resin, or silicone-based resin. However, the present disclosure is not limited thereto, and other inorganic or organic materials can be used.

A color filter buffer layer 160 can be disposed on the touch sensor unit 150. The color filter buffer layer 160 can be also disposed on the touch protection layer 152. The color filter buffer layer 160 can protect the touch sensor unit 150 from being damaged during a process of forming the color filters 171, 172, 173, and 174 and the black matrix 180 disposed on the touch sensor unit 150. In addition, the color filter buffer layer 160 can prevent penetration of moisture or oxygen from the outside to protect the touch sensor unit 150 from being deteriorated. The color filter buffer layer 160 can be formed of an inorganic insulating material having excellent or improved barrier properties. For example, the color filter buffer layer 160 can be formed of at least one inorganic insulating material selected from among silicon nitride (SiNx), silicon oxide (SiOx), aluminum oxide (AlOx), and silicon oxynitride (SiON), but the present disclosure is not limited thereto, and other materials, such as ceramics can be used. In addition, the color filter buffer layer 160 can compensate for a decrease in adhesion between the plurality of color filters 171, 172, 173, and 174 and the black matrix 180, and the touch sensor unit 150. For example, the color filter buffer layer 160 can be disposed on the touch sensor unit 150 so that the plurality of color filters 171, 172, 173, and 174, the black matrix 180, and the touch sensor unit 150 can be bonded to each other.

The plurality of color filters 171, 172, 173, and 174 and the black matrix 180 can be disposed on the color filter buffer layer 160. The plurality of color filters 171, 172, 173, and 174 and the black matrix 180 can absorb external light while maintaining high luminance of light emitted from the organic light emitting element 130 to thereby serve as an anti-reflection layer that minimizes a decrease in visibility and contrast ratio of the display device 100 due to the external light. The plurality of color filters 171, 172, 173, and 174 are disposed on the color filter buffer layer 160 to correspond to the plurality of sub-pixels SP1, SP2, SP3, and SP4, respectively. Each of the color filters 171, 172, 173, and 174 is independently disposed to correspond to each sub-pixel. The black matrix 180 can be disposed on the color filter buffer layer 160 to partition or provide separation for the plurality of color filters 171, 172, 173, and 174. The black matrix 180 can be disposed along boundaries of the sub-pixels SP1, SP2, SP3, and SP4. The black matrix 180 can be disposed to overlap the banks 125. Accordingly, color mixing between the sub-pixels SP1, SP2, SP3, and SP4 can be minimized.

The black matrix 180 can include a plurality of openings OA. The plurality of openings OA respectively overlap the plurality of sub-pixels SP1, SP2, SP3, and SP4. The plurality of openings OA overlap the emission areas of the plurality of sub-pixels SP1, SP2, SP3, and SP4 respectively, to transmit light emitted from the organic light emitting layer 132.

The display device 100 can have a pull-back structure. Specifically, a width of the opening OA is greater than that of the emission area. A width of the banks 125 defining the emission areas of the sub-pixels SP1, SP2, SP3, and SP4 is greater than a width of the black matrix 180 defining the openings OA. Accordingly, the width of the opening OA is greater than that of each of the sub-pixels SP1, SP2, SP3, and SP4. In this example, a portion of light emitted from the organic light emitting element can be emitted to a side surface thereof, so that a luminance viewing angle and a color viewing angle are excellent or improved. In various embodiments of the present disclosure, the width of the opening OA is greater than that of each of the sub-pixels SP1, SP2, SP3, and SP4 to provide a pull-back structure for each of the sub-pixels SP1, SP2, SP3, and SP4, but the present disclosure is not limited thereto. For example, only some of the sub-pixels SP1, SP2, SP3, and SP4 can be lesser than the opening OA so that the pull-back structure is provided only for some of the sub-pixels SP1, SP2, SP3, and SP4. Further, the amount of pull-back between the opening OA and the sub-pixels SP1, SP2, SP3, and SP4 can be different or adjusted to calibrate the amount of exposure by the banks without being completely covered by the black matrix to augment reduction of the occurrence of rainbow stain relating to a particular color due to the banks being exposed.

The black matrix 180 absorbs external light. Accordingly, degradation in visibility and contrast ratio of the display device 100 due to external light can be minimized. The black matrix 180 includes a base resin and a black material. The base resin can be at least one selected from among cardo-based resin, epoxy-based resin, acrylate-based resin, siloxane-based resin, and polyimide, but the present disclosure is not limited thereto. The black material can be a black pigment selected from among a carbon-based pigment, a metal oxide-based pigment, and an organic-based pigment. For example, the carbon-based pigment can be carbon black. For example, the metal oxide-based pigment can include titanium black (TiNxOy) and Cu—Mn—Fe-based black pigments, but the present disclosure is not limited thereto. For example, the organic-based pigment can be selected from among lactam black, perylene black, and aniline black, but the present disclosure is not limited thereto. In addition, an RGB black pigment including a red pigment, a blue pigment, and a green pigment can be used as the black material, but the present disclosure is not limited thereto.

The plurality of color filters 171, 172, 173, and 174 include a first color filter 171 corresponding to the first sub-pixel SP1, a second color filter 172 corresponding to the second sub-pixel SP2, a third color filter 173 corresponding to the third sub-pixel SP3, and a fourth color filter 174 corresponding to the fourth sub-pixel SP4. In various embodiments of the present disclosure, thicknesses of each of the plurality of color filters 171, 172, 173, and 174 can be the same, but the present disclosure is not limited thereto, and one or more of the color filters 171, 172, 173, and 174 can have different thicknesses from the other of the color filters 171, 172, 173, and 174, or all of the plurality of color filters 171, 172, 173, and 174 can have different thicknesses from each other for various reasons, such as to improve color light emission.

The second color filter 172 and the fourth color filter 174 can be alternately disposed in the first direction (the X-axis direction), and the first color filter 171 and the third color filter 173 can be alternately disposed in the second direction (the Y-axis direction) between the second color filter 172 and the fourth color filter 174. The first color filter 171 and the third color filter 173 can be disposed in a zigzag manner with the second color filter 172 and the fourth color filter 174.

Each of the plurality of color filters 171, 172, 173, and 174 can have a circular shape on a plane, but the present disclosure is not limited thereto. As another example, each of the plurality of color filters 171, 172, 173, and 174 can have an elliptical shape, or a polygonal shape such as a triangular shape, a quadrangular shape, a pentagonal shape, or a hexagonal shape, which is not particularly limited. Also, each of the plurality of color filters 171, 172, 173, and 174 can have tapered shape in cross section, where a width at the top of the taper is less than a width at the bottom of the taper as shown in FIG. 3. But the present disclosure is not limited thereto, and the cross-sectional shapes of the plurality of color filters 171, 172, 173, and 174 can have a more rounded top, or rounded top corner, and can be semi-ovals, semi-circular. Also, other shapes such as polygonal, stackings of two or more layers or other shapes are within the scope of the present disclosure so that the shapes are not particularly limited.

Each of the color filters 171, 172, 173, and 174 can correspond to the color of the corresponding sub-pixels SP1, SP2, SP3, and SP4. For example, when the first sub-pixel SP1 is a red sub-pixel, the first color filter 171 is a red color filter. When the second and fourth sub-pixels SP2 and SP4 are green sub-pixels, the second color filter 172 and the fourth color filter 174 are green color filters. When the third sub-pixel SP3 is a blue sub-pixel, the third color filter 173 is a blue color filter. The first color filter 171 transmits red light. Here, a wavelength of the red light can be about 620 nm to about 750 nm, but the present disclosure is not limited thereto. The second color filter 172 and the fourth color filter 174 transmit green light. Here, a wavelength of the green light can be about 495 nm to about 570 nm, but the present disclosure is not limited thereto. The third color filter 173 transmits blue light. Here, a wavelength of the blue light can be about 440 nm to about 495 nm, but the present disclosure is not limited thereto. In various embodiments, other colors or wavelengths of light can be used, including ultraviolet.

Each of the color filters 171, 172, 173, and 174 can include a transparent base resin and a color-development material. For example, the transparent base resin can be one selected from polyacrylate, polymethyl methacrylate, polyimide, polyvinyl alcohol, polyethylene, polypropylene, polystyrene, polyethylene terephthalate, and the like, but the present disclosure is not limited thereto. The color-development material absorbs light in a specific wavelength band and transmits light in remaining wavelength bands. For example, the red color filter includes a red color-development material that transmits light in a red wavelength band and absorbs light in green and blue wavelength bands. For example, the red color-development material can be a phenylene-based compound or a diketo-pyrrolopyrrole-based compound. For example, the green color-development material can be a phthalocyanine-based compound. For example, the blue color-development material can be a copper phthalocyanine-based compound or an anthraquinone-based compound. However, the color-development material is not limited thereto, and any material that transmits light in red, blue, and green wavelength bands can be used without limitation. Each of the plurality of color filters 171, 172, 173, and 174 is arranged to correspond to the emission area of the sub-pixel SP1, SP2, SP3, or SP4 corresponding thereto. Accordingly, internal light emitted from each of the first sub-pixel SP1, the second sub-pixel SP2, the third sub-pixel SP3, and the fourth sub-pixel SP4 passes through the corresponding one of the color filter 171, 172, 173, or 174. For example, red light emitted from the first sub-pixel SP1 passes through the first color filter 171. On the other hand, when external light is incident, the external light corresponding to an absorption wavelength of the color-development material included in each of the color filters 171, 172, 173, and 174 is absorbed by the color filter 171, 172, 173, or 174. External light not absorbed by the color filter 171, 172, 173, or 174 is reflected by the cathode 133 and passes through the color filter 171, 172, 173, or 174 again. Reflected light corresponding to the absorption wavelength of the color-development material included in each of the color filters 171, 172, 173, and 174 is absorbed by the color filter 171, 172, 173, or 174. Accordingly, degradation of display quality due to the external light can be minimized.

Each of the plurality of color filters 171, 172, 173, and 174 can include a first region AR1 and a second region AR2. The first region AR1 overlaps the emission area of the sub-pixel SP1, SP2, SP3, or SP4 corresponding thereto. The second region AR2 surrounds the first region AR1. The second region AR2 overlaps an edge of the black matrix 180 and an edge of the bank 125 defining the emission area.

The second region AR2 includes a first sub-region sub-AR1 and a second sub-region sub-AR2. The first sub-region sub-AR1 surrounds the first region AR1. The first sub-region sub-AR1 comes into contact with a side surface of the black matrix 180 and surrounds the black matrix 180. The first sub-region sub-AR1 is located between the first region AR1 and the second sub-region sub-AR2. As described above, in the display device 100, the width of the bank 125 is greater than the width of the black matrix 180. Thus, the display device 100 has the pull-back structure in which the width of the opening OA is greater than the width of the emission area. A width of the first sub-region sub-AR1 can be equal to a linear distance from one end of the black matrix 180 to one end of the bank 125 corresponding thereto.

The second sub-region sub-AR2 is located outside the first sub-region sub-AR1. The second sub-region sub-AR2 is disposed to contact and cover at least a portion of an upper surface of the black matrix 180. Accordingly, the sum of a thickness of the black matrix 180 and a thickness of the second sub-region sub-AR1 can be equal to a thickness of the first region AR1.

A plurality of holes H are provided in an edge of the first region AR1. The holes H provided in each of the color filters 171, 172, 173, and 174 improve a luminance viewing angle and a color viewing angle of the display device 100. In addition, the plurality of holes H can suppress rainbow stain. The plurality of holes H are provided at positions corresponding to edges of the emission areas of the sub-pixels SP1, SP2, SP3, and SP4. The plurality of holes H are respectively formed to pass through the first regions AR1 of the color filters 171, 172, 173, and 174 in a thickness direction of the color filters 171, 172, 173, and 174. Accordingly, each of the plurality of holes H exposes at least a portion of the color filter buffer layer 160.

As described above, when the holes H are provided at the edge of the first region AR1 overlapping the emission area, a difference in refractive index between the color filters 171, 172, 173, and 174 and the holes H occurs. For example, the color filters 171, 172, 173, and 174 can be formed of a material having a refractive index of 1.5 or more or 1.5 to 1.8. The holes H are air gaps and can have a refractive index of 1.0±0.2. Accordingly, a portion of light emitted from front surfaces of the color filters 171, 172, 173, and 174 in a front direction is refracted at the edge of the first region AR1 provided with the holes H. For example, at least a portion of light emitted from the organic light emitting element 130 is totally reflected due to a difference in refractive index between the holes H and the color filters 171, 172, 173, and 174. For example, when the refractive index of the color filters 171, 172, 173, and 174 is 1.5 and the refractive index of the holes H that are air gaps is 1.0, a total reflection angle can be 42°. Accordingly, a portion of the light emitted in the front direction can be totally reflected at the edge of the first region AR1 of the color filters 171, 172, 173, or 174 and be emitted in a lateral direction. Thus, a luminance viewing angle and a color viewing angle can be improved.

Each of the plurality of holes H can be tilted at a predetermined angle. Each of the plurality of holes H can be tilted toward a side surface of the emission area. Each of the plurality of holes H can be tilted outwardly from inside of the emission area. For example, each of the plurality of holes H can be tilted from the first region AR1 toward the second region AR2. For example, in a cross-section, the hole H provided at a left edge of the first region AR1 can be tilted leftward of FIG. 3, and the hole H provided at a right edge of the first region AR1 can be tilted rightward of FIG. 3. Accordingly, an angle between the hole H and an upper surface of the color filter buffer layer 160 can be less than 90° in a cross-section. As described above, when each of the plurality of holes H is tilted to an outside of the emission area, a viewing angle is further increased. Accordingly, a color viewing angle and a luminance viewing angle can be further improved. For example, a tilt angle of each of the plurality of holes H can be 1° to 25° or 5° to 15° from a line perpendicular to the color filter buffer layer 160, and within this range, a color viewing angle and a luminance viewing angle can be improved while high optical characteristics of the display device 100 is maintained.

In various embodiments of the present disclosure, the plurality of holes H are tilted leftward or rightward based on whether the plurality of holes are located at the left edge or the right edge of the first region AR1, for example. But the present disclosure is not limited thereto, as at least one of the plurality of holes H at the left edge of the first region AR1 can be tilted rightward, and at least one of the plurality of holes H at the right edge of the first region AR1 can be tilted leftward to calibrate the color viewing angle and the luminance viewing angle. Further, among the plurality of holes H at the left edge, at least one of the plurality of holes H can have a tilt angle of 0° or very close to 0°, while the others are tilted leftward or rightward. Also, among the plurality of holes H at the right edge, at least one of the plurality of holes H can have a tilt angle of 0° or very close to 0°, while the others are tilted leftward or rightward.

In embodiments of the present disclosure, the plurality of holes H are provide as having a straight path through the color filters 171, 172, 173, or 174, but the present disclosure is not limited thereto, and one or more of the plurality of holes H can be curved from one end to another end of the one or more holes H, or can be angled. When curved or angled, the hole H can start off with a tilt and end being perpendicular to the color filter buffer layer 160, or can start off being perpendicular to the color filter buffer layer 160 and end being tilted. In various embodiments of the present disclosure, the another end of the hole H at the top of the color filters 171, 172, 173, or 174 can be tilted opposite to the one end that exposes the color filter buffer layer 160.

The plurality of holes H provided in each of the first regions AR1 of the color filters 171, 172, 173, and 174 can prevent or reduce rainbow stain. As described above, in order to secure a viewing angle, the display device has the pull-back structure in which the width of the openings OA of the black matrix 180 is greater than the width of the emission areas of the sub-pixels SP1, SP2, SP3, and SP4. For example, the width of the banks 125 is greater than that of the black matrix 180. Accordingly, one end of the bank 125 protrudes more than one end of the black matrix 180 and thus, an edge portion of the bank 125 is exposed without overlapping the black matrix 180. As described above, rainbow stain can be caused by mutual interference of light due to a regular pattern shapes of the color filters 171, 172, 173, and 174 and a regular arrangement of the exposed banks 125. This rainbow stain degrades visibility and affects display quality. The plurality of holes H provided in each of the first regions AR1 of the color filters 171, 172, 173, and 174 can reduce regularity described above and refract a portion of the emitted light due to a difference in refractive index, thereby minimizing visual recognition of rainbow stain. Accordingly, display quality of the display device 100 can be improved.

The plurality of holes H can be arranged along a circumference of the edge of the first region AR1 on a plane in an annular pattern for example. The plurality of holes H can be arranged in a plurality of columns. For example, the plurality of holes H can be arranged in a plurality of columns in a direction from outside to inside of the color filters 171, 172, 173, and 174 on a plane. For example, the plurality of holes H can be formed in a plurality of columns along the circumference of the edge of the first region AR1. FIGS. 2 to 4 illustrate that the plurality of holes H are arranged in two columns along the edge of the first region AR1, but this is an example, and the present disclosure is not limited thereto. For example, the plurality of holes H can be arranged in 2 to 20 columns, 2 to 10 columns, or 2 to 4 columns in a direction from the outside to the inside of the color filters 171, 172, 173, and 174. Within this range, a color viewing angle and a luminance viewing angle can be improved, and rainbow stain can be suppressed while maintaining high optical characteristics of the display device 100.

In addition, in FIG. 2, it is illustrated that each column includes 32 holes H, but this is only an example and the present disclosure is not limited thereto. For example, each column can include 8 or more, or 8 to 100, 8 to 50 or 20 to 50 holes H. Within this range, a color viewing angle and a luminance viewing angle can be improved, and rainbow stain can be suppressed while maintaining high optical characteristics of the display device 100.

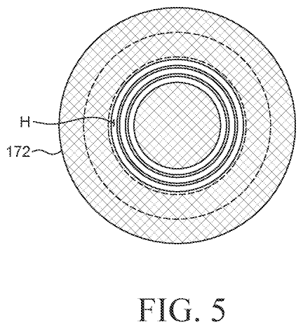

For example, each hole H can have a circular shape or elliptical shape on a plane. As another example, each hole H can have a polygonal shape such as a quadrangular shape, a pentagonal shape, or a hexagonal shape. However, the present disclosure is not limited thereto, and each hole can be of various geometric shapes. FIG. 5 is a view for explaining a structure in which a hole has a line shape or an annular shape in another example embodiment of the present disclosure. Referring to FIG. 5, each of the plurality of holes H can have a line shape or an annular shape. For example, each of the plurality of holes H can be formed in a line shape or an annular shape along circumferences of the color filters 171, 172, 173, and 174.

For example, a diameter of each of the holes H can be 0.1 μm to 5 μm or 0.3 μm to 2 μm. Within this range, a color viewing angle and a luminance viewing angle can be excellent or improved, and rainbow stain can be prevented or reduced. For example, a distance between the holes H adjacent to each other can be 0.1 μm to 5 μm or 0.3 μm to 2 μm, and within this range, a color viewing angle and a luminance viewing angle can be excellent or improved, and rainbow stain can be prevented or reduced. However, the present disclosure is not limited thereto, and the diameter of the holes H and the distance between the holes H can vary as needed or depending on a design structure. Further, in the drawings, it is illustrated that the holes H are regularly arranged, but the present disclosure is not limited thereto. The holes H can be randomly formed at the edge of the first region AR1 as needed or depending on a design structure.

In the drawings, each of the color filters 171, 172, 173, and 174 can have the holes H having the same shapes, depths, tilt angles, diameters, and numbers, but the present disclosure is not limited thereto. Depending on the color of each color filter 171, 172, 173, 174, the shapes, depths, tilt angles, diameters, and numbers of holes H provided in each of the color filters 171, 172, 173, and 174 can be different.

In various embodiments of the present disclosure, the plurality of holes H can be provided in multiple annular patterns that can encircle a center region of each color filter 171, 172, 173, 174, and one annular pattern can be nested within a larger annular pattern, but the present disclosure is not limited thereto, and various patterns such as a rectangular pattern, a square pattern, a triangular pattern, an oval pattern, a hexagonal pattern, a polygonal pattern can be used, and each can be nested as an inner pattern and an outer pattern. In embodiments of the present disclosure, the inner pattern can have a diameter that is less than a diameter of the outer pattern. Accordingly, the inner pattern and the outer pattern can have different sizes, and the inner pattern can be smaller than the outer pattern.

An overcoating layer 190 can be disposed to cover the plurality of color filters 171, 172, 173, and 174 and the black matrix 180. The overcoating layer 190 can fill the plurality of holes H provided at the edges of the first regions AR1. Accordingly, the overcoating layer 190 planarizes upper portions of the plurality of color filters 171, 172, 173, and 174 and the black matrix 180. For example, the overcoating layer 190 can be formed of a transparent resin such as acrylic resin, silicone resin, polyester resin, or epoxy resin, but is not limited thereto. Other organic or inorganic materials can be used.

The display device according to an example embodiment of the present disclosure has the pull-back structure in which the width of the openings OA of the black matrix 180 is greater than the width of the emission areas of the sub-pixels SP1, SP2, SP3, and SP4. In addition, the display device according to an example embodiment of the present disclosure includes the plurality of holes H at the edges of the first regions AR1 of the color filters 171, 172, 173, and 174. As described above, the light emitted in the front direction is shifted in a viewing angle direction by the holes H provided at the edge of the first region AR1, so that advantages of an excellent or improved luminance viewing angle and an excellent or improved color viewing angle are provided. In addition, although a partial area of the bank 125 is not covered by the black matrix 180 and partially exposed due to the pull-back structure, rainbow stain can be prevented or reduced by the hole H, and excellent or improved display quality can be advantageously provided.

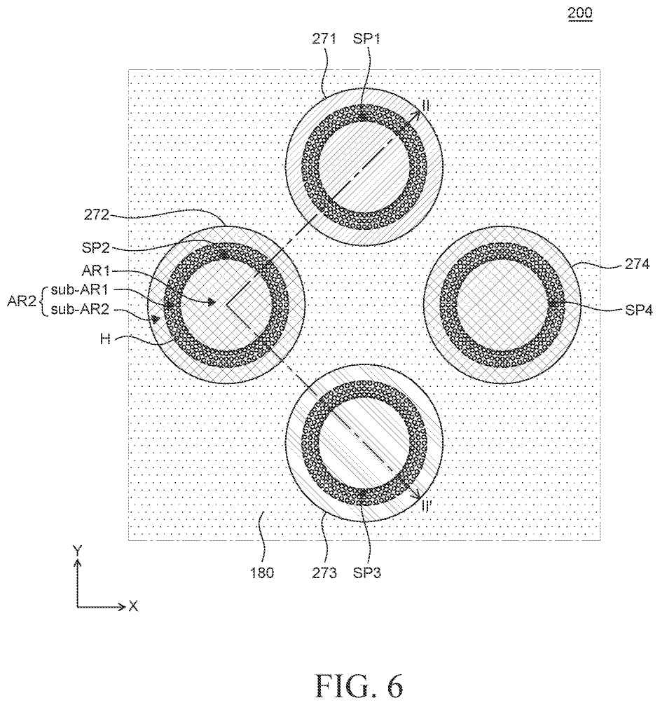

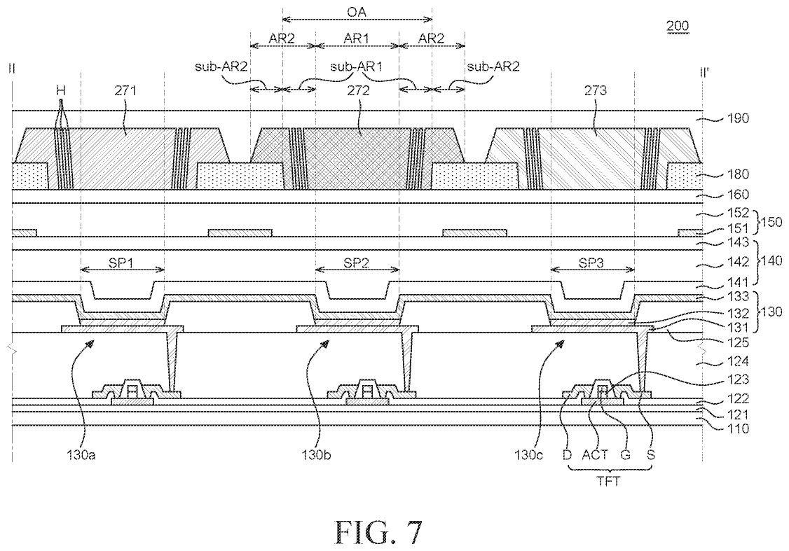

FIG. 6 is an enlarged plan view of one pixel of a display device according to another example embodiment of the present disclosure. FIG. 7 is a cross-sectional view taken along II-II′ of FIG. 6. A display device 200 shown in FIGS. 6 and 7 is substantially identical to the display device 100 shown in FIGS. 1 to 4 except for positions where a plurality of holes are provided. Specifically, the display device 200 shown in FIGS. 6 and 7 is substantially identical to the display device 100 shown in FIGS. 1 to 4 except that a plurality of holes are provided in the first sub-region of the second region instead of the edge of the first region. Accordingly, descriptions of duplicated configurations will be omitted.

The plurality of holes H can be provided in the first sub-region sub-AR1 of the second region AR2 of each of color filters 271, 272, 273, and 274. The holes H provided in the first sub-region sub-AR1 are formed to pass through the first sub-region sub-AR1 of each of the color filters 271, 272, 273, and 274. Accordingly, the holes H provided in the first sub-region sub-AR1 expose at least a portion of the color filter buffer layer 160.

The holes H provided in the first sub-region sub-AR1 can be formed in a plurality of columns from outside to inside of the color filters 271, 272, 273, and 274. For example, the plurality of holes H can be arranged in 2 to 20 columns, 2 to 6 columns, or 2 to 4 columns in a direction from the outside to the inside of the color filters 271, 272, 273, and 274. In this example, each column can include 8 or more, 8 to 100, 8 to 50, or 20 to 50 holes H.

The holes H provided in the first sub-region sub-AR1 can be tilted toward an outer surface of the emission area. For example, in a cross-section, the holes H located on left side of the first sub-region sub-AR1 can be tilted leftward of FIG. 7, and the holes H provided on right side of the first sub-region sub-AR1 can be tilted rightward of FIG. 7. For example, a tilt angle of each of the plurality of holes H can be 1° to 25° or 5° to 15° from a line perpendicular to the color filter buffer layer 160.

Other characteristics of the holes H provided in the first sub-region sub-AR1 are substantially identical to those of the holes provided at the edge of the first region described in FIGS. 1 to 4 except for positions of the holes H. Accordingly, redundant description of shapes, arrangement structures, tilt angles, and the like of the holes H will be omitted.

The display device 200 according to another example embodiment of the present disclosure is provided in that the plurality of holes H are provided in the first sub-area sub-AR1 of the second region AR2. As described above, since the holes H are provided in edges of the color filters 271, 272, 273, and 274, a luminance viewing angle and a color viewing angle can be improved. In particular, the first sub-region sub-AR1 overlaps a region in which a partial region of the bank 125 is not covered by the black matrix 180 and is exposed due to the pull-back structure. As the plurality of holes H are provided at such a location, even though a partial area of the bank 125 is not covered by the black matrix 180 and exposed, rainbow stain is suppressed, and display quality is excellent or improved.

FIGS. 6 and 7 illustrate that the plurality of holes H are provided only in the first sub-region sub-AR1 of the second region AR2 of each of the color filters 271, 272, 273, and 274, but the present disclosure is not limited thereto. The plurality of holes H can be provided in each of the edge of the first region AR1 and the first sub-area sub-AR1 of the second region AR2 as needed or depending on a design structure.

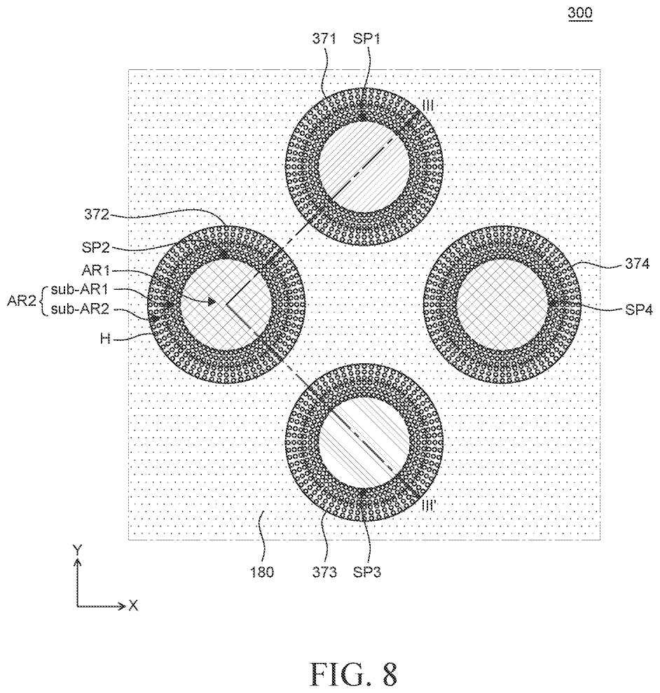

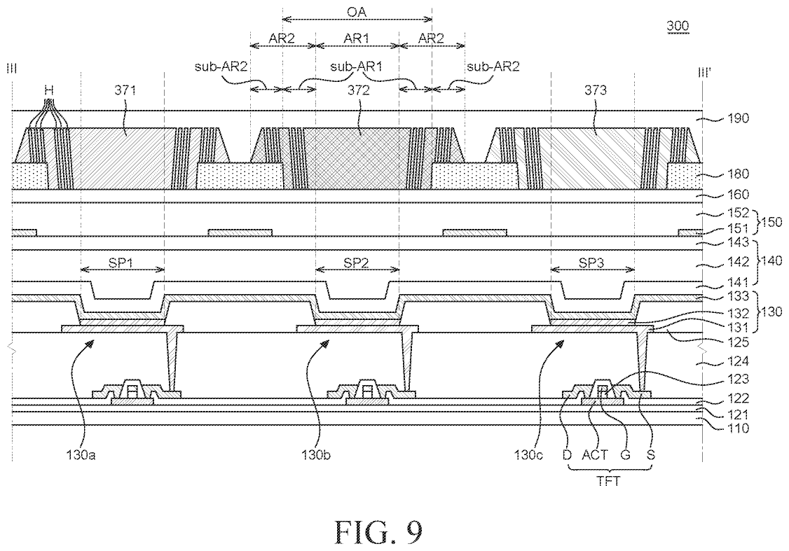

FIG. 8 is an enlarged plan view of one pixel of a display device according to still another example embodiment of the present disclosure. FIG. 9 is a cross-sectional view taken along III-III′ of FIG. 8. A display device 300 shown in FIGS. 8 and 9 is substantially identical to the display device 100 shown in FIGS. 1 to 4 and the display device 200 shown in FIGS. 6 to 7 except for positions where a plurality of holes are provided. Specifically, the display device 300 shown in FIGS. 8 and 9 is substantially identical to the display device 100 shown in FIGS. 1 to 4 and the display device 200 shown in FIGS. 6 to 7 except that a plurality of holes are provided in each of the first sub-area sub-AR1 and the second sub-region sub-AR2 of the second region AR2. Accordingly, descriptions of overlapping configurations will be omitted. Accordingly, descriptions of duplicated configurations will be omitted.

Referring to FIGS. 8 and 9, each of the color filters 371, 372, 373, and 374 includes a plurality of holes H in each of the first sub-region sub-AR1 and the second sub-region sub-AR2 of the second region AR2. The holes H provided in the first sub-region sub-AR1 are formed to pass through the first sub-region sub-AR1 of each of the color filters 371, 372, 373, and 374. Accordingly, the holes H provided in the first sub-region sub-AR1 expose at least a portion of the color filter buffer layer 160.

Other features of the holes H provided in the first sub-region sub-AR1 are substantially identical to those of the holes H provided in the first sub-region sub-AR1 in the display device 200 of FIGS. 6 and 7. Accordingly, redundant descriptions will be omitted.

The holes H provided in the second sub-region sub-AR2 are formed to pass through the second sub-region sub-AR2 in a thickness direction. As described above, the second sub-region sub-AR2 is an area that is disposed to cover at least a portion of the upper surface of the black matrix 180. Accordingly, the holes H provided in the second sub-region sub-AR2 expose at least a portion of the black matrix 180.

The holes H provided in the second sub-region sub-AR2 can be formed in a plurality of columns from outside to inside of the color filters 371, 372, 373, and 374. For example, the holes H provided in the second sub-region sub-AR2 can be arranged in 2 to 20 columns, 2 to 6 columns, or 2 to 4 columns in a direction from the outside to the inside of the color filters 371, 372, 373, and 374. In this example, each column can include 8 or more, 8 to 100, 8 to 50, or 20 to 50 holes H.

The holes H provided in the second sub-region sub-AR2 can be tilted toward an outer surface of the emission area. For example, in a cross-section, the holes H located on left side of the second sub-region sub-AR2 can be tilted leftward of FIG. 9, and the holes H provided on right side of the second sub-region sub-AR2 can be tilted rightward of FIG. 9. For example, a tilt angle of each of the plurality of holes H can be 1° to 25° or 5° to 15° from a line perpendicular to the color filter buffer layer 160.

The display device 300 according to still another example embodiment of the present disclosure is provided in that the plurality of holes H are provided in each of the first sub-region sub-AR1 and the second sub-region sub-AR2 of the second region AR2. Accordingly, a larger number of holes H are provided in edges of the color filters 371, 372, 373, and 374, so that a luminance viewing angle and a color viewing angle can be further improved. In addition, although a partial area of the bank 125 is not covered by the black matrix 180 and is exposed by the pull-back structure, rainbow stain is prevented or reduced by the holes H and thus, display quality is excellent or improved.

For reference, the plurality of holes H can be provided in at least one of the edge of the first region AR1, and the first sub-region sub-AR1 and the second sub-region sub-AR2 of the second region AR2. For example, the holes can be provided in two or all three areas, as well as each of the three areas described above. In all of these examples, efficiency of the light emitted in the lateral direction is increased, so that a color viewing angle and a luminance viewing angle are excellent or improved, and rainbow stain can be prevented or reduced.

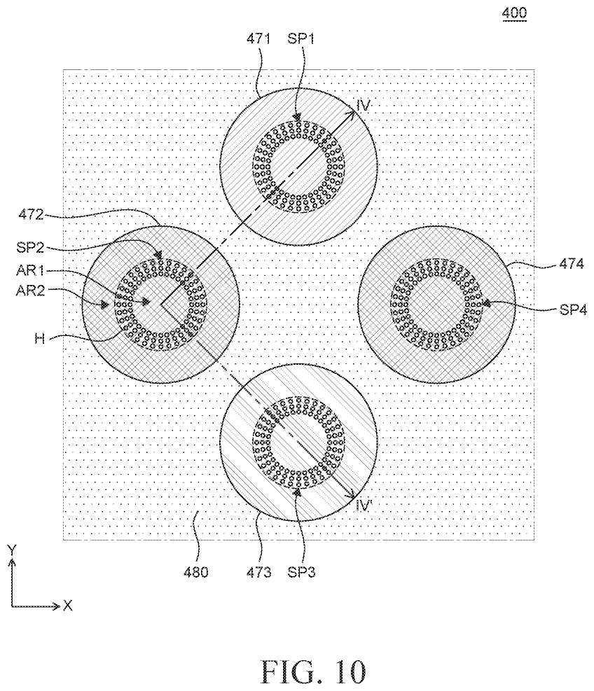

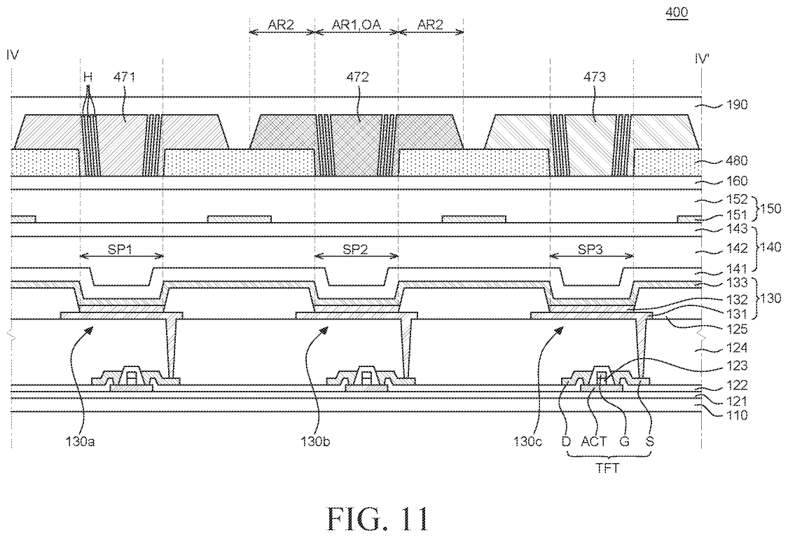

FIG. 10 is an enlarged plan view of one pixel of a display device according to still another example embodiment of the present disclosure. FIG. 11 is a cross-sectional view taken along IV-IV′ of FIG. 10. A display device 400 shown in FIGS. 10 to 11 is substantially identical to the display device 100 shown in FIGS. 1 to 4 except for a width of openings of a black matrix. Accordingly, descriptions of duplicated components will be omitted.

Referring to FIGS. 10 to 11, a width of openings OA of a black matrix 480 is equal to the width of the emission area of each of the sub-pixels SP1, SP2, SP3, and SP4. The width of the banks 125 defining the emission areas of the sub-pixels SP1, SP2, SP3, and SP4 can be equal to the width of the black matrix 480 defining the openings OA. Accordingly, the banks 125 completely overlap the black matrix 480 corresponding thereto. Accordingly, there is an advantage in that rainbow stain due to a regular arrangement of the exposed banks does not occur, so display quality is excellent or improved.

In the display device 400 according to the example embodiment, an area of the black matrix 480 is larger than that of the display devices of FIGS. 1 to 9 to which the pull-back structure is applied. Accordingly, there are advantages in that it is easy to absorb external light and reflected light and thus reflective visibility is excellent or improved.

Each of the plurality of color filters 471, 472, 473, and 474 includes a first region AR1 and a second region AR2. The first region AR1 overlaps the emission area of the sub-pixel SP1, SP2, SP3, or SP4 corresponding thereto. The first region AR1 comes into contact with a side surface of the black matrix 480 and surrounds the black matrix 480. The second region AR2 surrounds the first region AR1. The second region AR2 overlaps at least a portion of the bank 125 defining the emission area and at least a portion of the black matrix 480 defining the opening OA. The second region AR2 is disposed to cover at least a portion of an upper surface of the black matrix 480. Accordingly, the sum of a thickness of the black matrix 480 and a thickness of the second region AR2 can be equal to a thickness of the first region AR1.

A plurality of holes H are provided at the edge of the first region AR1. The holes H provided in each of the color filters 471, 472, 473, and 474 improve a luminance viewing angle and a color viewing angle of the display device 400. In the display device 400 according to the example embodiment, the width of the opening OA of the black matrix 480, the width of the emission areas of the sub-pixels SP1, SP2, SP3, and SP4, and a width of the first region AR1 are respectively equal to one another. In this example, the luminance viewing angle and color viewing angle can be reduced. However, light is emitted in the lateral direction by the holes H provided at the edge of the first region AR1, so the luminance viewing angle and color viewing angle are excellent or improved. The plurality of holes H are provided in positions corresponding to edges of the emission areas of the sub-pixels SP1, SP2, SP3, and SP4. The plurality of respective holes H are formed to pass through the first regions AR1 of the color filters 471, 472, 473, and 474 in a thickness direction of the color filters 471, 472, 473, and 474. Accordingly, each of the plurality of holes H exposes at least a portion of the color filter buffer layer 160.

Other characteristics of the holes H provided at the edge of the first region AR1 are substantially identical to those of the holes H provided at the edge of the first region AR1 in the display device 100 of FIGS. 1 to 4. Accordingly, redundant description will be omitted.

The display device 400 according to still another example embodiment of the present disclosure is provided in that the width of the opening OA of the black matrix 480 is equal to the width of the emission area of each of the sub-pixels SP1, SP2, SP3, and SP4, and each of the color filters 471, 472, 473, and 474 has the plurality of holes H at the edge of the first region AR1. Accordingly, a rainbow stain phenomenon can be fundamentally eliminated, and the area of the black matrix 480 is larger than that of the display device having the pull-back structure, so that reflectivity can be significantly lowered and reflective visibility can be improved. In addition, light emitted in the front direction is shifted in a viewing angle direction by the provided holes H, so there is an advantage in that a luminance viewing angle and a color viewing angle are excellent or improved.

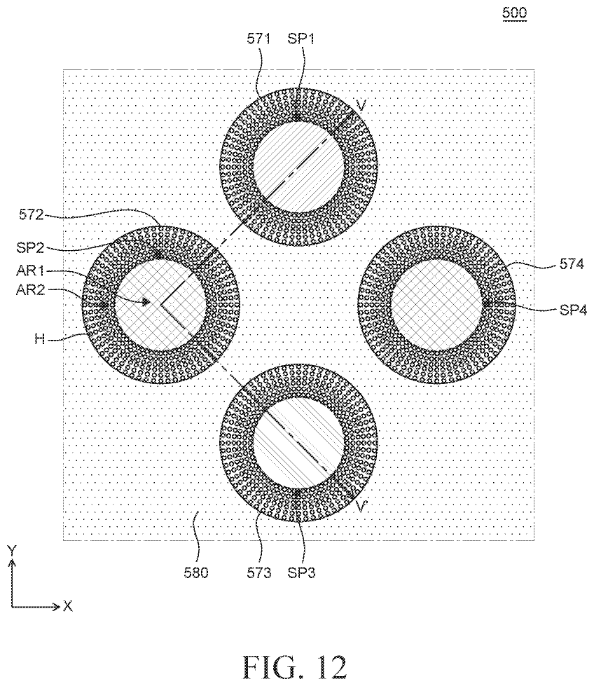

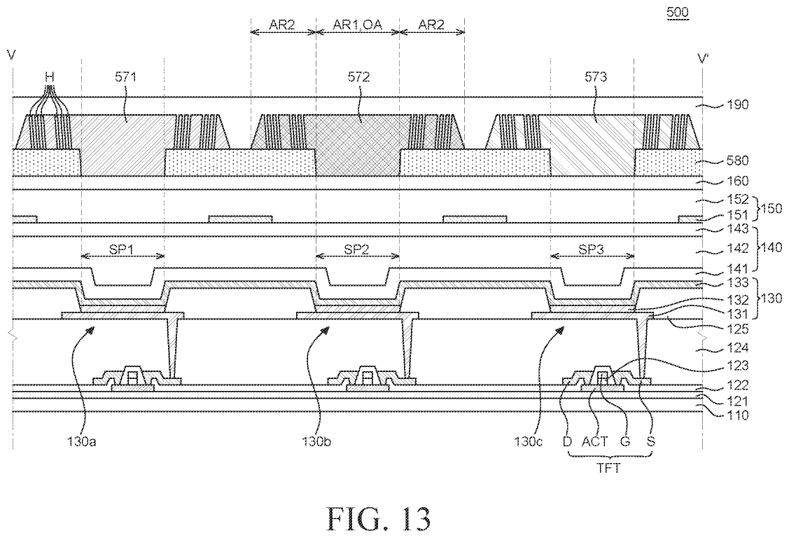

FIG. 12 is an enlarged plan view of one pixel of a display device according to still another example embodiment of the present disclosure. FIG. 13 is a cross-sectional view taken along V-V′ of FIG. 12. A display device 500 shown in FIGS. 12 and 13 is substantially identical to the display device 400 shown in FIGS. 10 and 11 except for positions where a plurality of holes are provided. Accordingly, descriptions of duplicate components will be omitted.

Referring to FIGS. 12 and 13, a plurality of holes H are formed in second regions AR2 of color filters 571, 572, 573, and 574. The holes H provided in the second region AR2 are formed to pass through the second region AR2 in a thickness direction. As described above, the second region AR2 is disposed to cover at least a portion of an upper surface of the black matrix 580. Accordingly, the holes H provided in the second region AR2 expose at least a portion of the black matrix 580.

The holes H provided in the second region AR2 can be formed in a plurality of columns from outside to inside of the color filters 571, 572, 573, and 574. For example, the holes H provided in the second region AR2 can be arranged in 2 to 20 columns, 2 to 6 columns, or 2 to 4 columns in a direction from the outside to the inside of the color filters 571, 572, 573, and 574. In this example, each column can include 8 or more, 8 to 100, 8 to 50, or 20 to 50 holes H.

The holes H provided in the second region AR2 can be tilted toward an outer surface of the emission area. For example, in a cross-section, the holes H located on left side of the second region AR2 can be tilted leftward of FIG. 13, and the holes H provided on right side of the second region AR2 can be tilted rightward of FIG. 13. For example, a tilt angle of each of the plurality of holes H can be 1° to 25° or 5° to 15° from a line perpendicular to the color filter buffer layer 160.

The display device 500 according to still another example embodiment of the present disclosure is provided in that a width of openings OA of the black matrix 580 is equal to the width of the emission area of each of the sub-pixels SP1, SP2, SP3, and SP4, and each of the color filters 571, 572, 573, and 574 has the plurality of holes H in the second region AR2. Accordingly, compared to the display device having the pull-back structure, an area of the black matrix 580 is wider, thereby lowering reflectivity significantly and reflective visibility can be improved. In addition, light emitted in the front direction can be shifted in a viewing angle direction by the holes H provided in the second region AR2. Therefore, since the display device 500 according to the example embodiment does not apply the pull-back structure thereto, a rainbow stain phenomenon caused by exposed bank areas can be fundamentally eliminated, and a luminance viewing angle and a color viewing angle are excellent or improved even without applying the pull-back structure.

In FIGS. 10 and 11, it is illustrated that the plurality of holes H are provided only at the edge of the first region AR1 of each of the color filters 471, 472, 473, and 474. In FIGS. 12 and 13, it is illustrated that the plurality of holes H are provided only in the second region AR2 of each of the color filters 571, 572, 573, and 574. However, the present disclosure is not limited thereto. A plurality of holes can be provided in each of the edge of the first region and the second region in a display device to which the pull-back structure is not applied, as needed or according to a design structure. In this example, since a larger number of holes are provided at the edges of the color filters, a color viewing angle and a luminance viewing angle can be further improved.

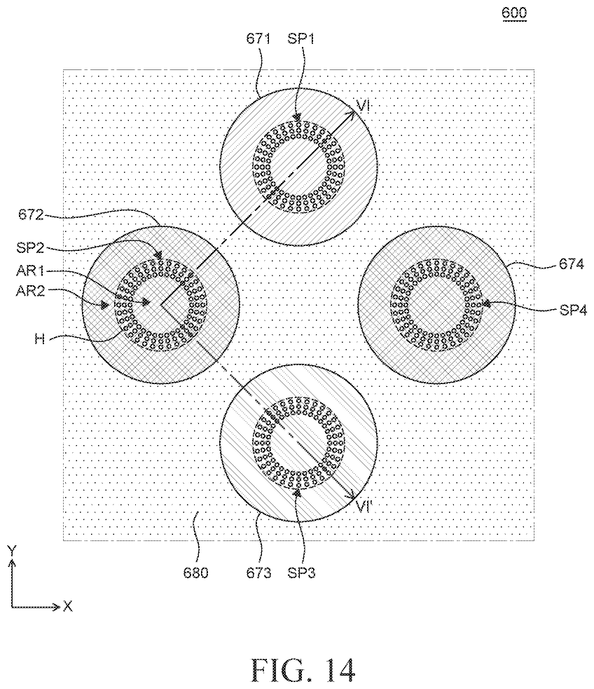

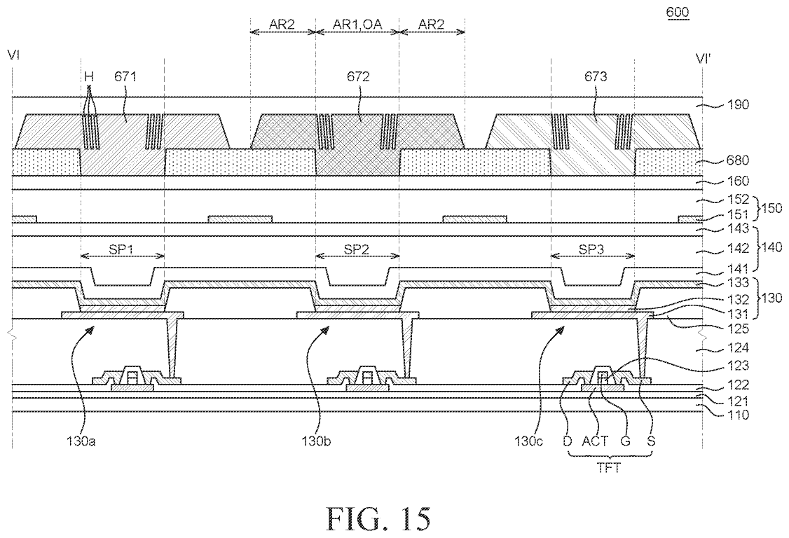

FIG. 14 is an enlarged plan view of one pixel of a display device according to still another example embodiment of the present disclosure. FIG. 15 is a cross-sectional view taken along VI-VI′ of FIG. 14. A display device 600 shown in FIGS. 14 and 15 is substantially identical to the display device 400 shown in FIGS. 10 and 11 except for shapes of a plurality of holes. Accordingly, descriptions of duplicate components will be omitted.

Referring to FIGS. 14 and 15, color filters 671, 672, 673, and 674 have a plurality of holes H in edges of the first regions AR1. Each of the plurality of holes H can be formed in a shape of a groove that does not completely pass through the first region AR1 in a thickness direction, but passes through only a partial area of the first region AR1 from an upper surface of the first region AR1 in the thickness direction. Accordingly, the holes H provided in the first region AR1 do not expose the color filter buffer layer 160. As described above, even if the plurality of holes H are formed to pass through only a portion of the first region AR1, total reflection is possible due to a difference in refractive index between the area where the holes H are formed and the color filters 671, 672, 673, and 674. Accordingly, light emitted in the front direction is shifted in a viewing angle direction, so that a luminance viewing angle and a color viewing angle can be improved.

As described above, when the holes H do not completely penetrate the color filters 671, 672, 673, and 674 in the thickness direction of the color filters 671, 672, 673, and 674, but only penetrate a portion of the color filters, a process is facilitated and productivity is high.

For example, the holes H provided in the first region AR1 can be formed to have a depth of 30% to 70% or 40% to 60% of a total thickness of the color filters 671, 672, 673, and 674. Within this range, an effect of improving a luminance viewing angle and a color viewing angle is excellent or improved. However, the present disclosure is not limited thereto and the depth of the hole H can be changed according to a design structure. For example, a depth of as shallow as 1% to as deep as 99% is within the scope of the present disclosure.

The holes H provided in the first region AR1 of each of the color filters 671, 672, 673, and 674 can be tilted toward an outer surface of the emission area. For example, in a cross-section, the holes H located on a left side of the first region AR1 can be tilted leftward of FIG. 15, and the holes H located on a right side of the first region AR1 can be tilted rightward of FIG. 15. For example, a tilt angle of each of the plurality of holes H can be 1° to 25° or 5° to 15° from a line perpendicular to the color filter buffer layer 160.

The holes H provided in the first region AR1 can be formed in a plurality of columns from outside to inside of the color filters 671, 672, 673, and 674. For example, the holes H provided in the first region AR1 can be arranged in 2 to 20 columns, 2 to 6 columns, or 2 to 4 columns in a direction from the outside to the inside of the color filters 671, 672, 673, and 674. In this example, each column can include 8 or more, 8 to 100, 8 to 50, or 20 to 50 holes H. However, the present disclosure is not limited thereto. The number of holes can be as low as 1, and as high as hundreds.

For example, a diameter of each of the holes H can be 0.1 μm to 5 μm or 0.3 μm to 2 μm, and a distance between the holes H adjacent to each other can be 0.1 μm to 5 μm or 0.3 μm to 2 μm, but the present disclosure is not limited thereto. Each of the holes H need not have a constant diameter, but can have a diameter that varies, whereby the diameter can increase or decrease in going from one end to another end of the hole, or an entrance and an exit can have the same diameter but an interior of the hole have a different diameter.

In the display device 600 according to the example embodiment, the holes H provided in the first region AR1 are formed to pass through only partial areas of the color filters 671, 672, 673, and 674 without completely passing through the color filters 671, 672, 673, and 674 in the thickness direction thereof. Accordingly, a process of forming the holes H is facilitated and productivity is excellent or improved, and a luminance viewing angle and a color viewing angle are excellent or improved due to the holes H provided in the first region AR1. In addition, since the pull-back structure is not applied thereto, there are advantages in that it is possible to fundamentally solve rainbow stain caused by exposed bank areas, and reflective visibility is also excellent or improved.

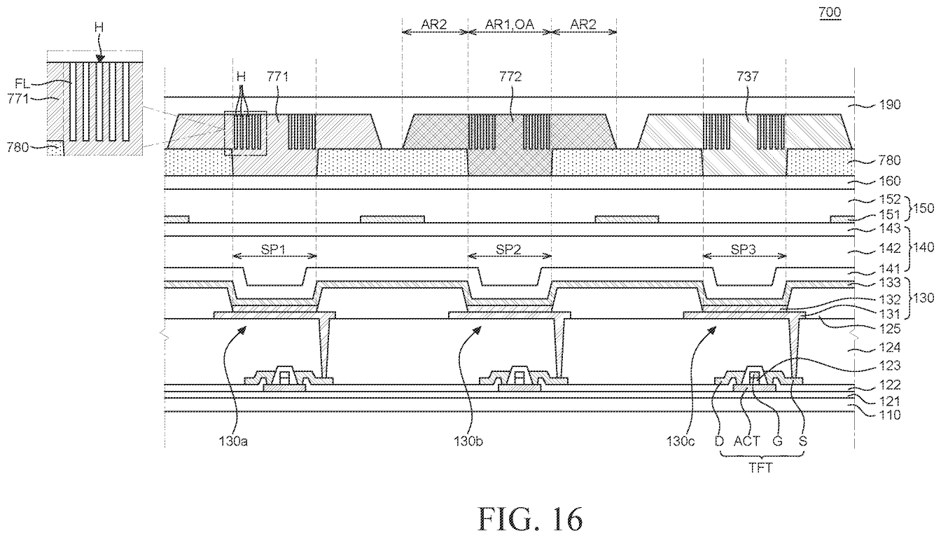

FIG. 16 is a schematic cross-sectional view of a display device according to still another example embodiment of the present disclosure. A display device 700 shown in FIG. 16 is substantially identical to the display device 600 shown in FIGS. 14 and 15 except for a structure of a plurality of holes and further inclusion of a pillar. Accordingly, descriptions of duplicate components will be omitted.

Referring to FIG. 16, each of color filters 771, 772, 773, and 774 includes a plurality of holes H in an edge of the first region AR1. Each of the plurality of holes H can be formed in a shape of a groove that does not completely pass through the first region AR1 in a thickness direction, but passes through only a partial area of the first region AR1 from an upper surface of the first region AR1 in the thickness direction. The plurality of holes H formed as described above shift a portion of the light emitted from the organic light emitting element 130 in a viewing angle direction. However, the present disclosure is not limited thereto, and the plurality of holes H can be formed to completely pass through the first region AR1 in the thickness direction. However, in the example of forming a plurality of holes in the shape of grooves, there is an advantage in terms of facilitating a process.

The holes H provided in the first region AR1 of each of the color filters 771, 772, 773, and 774 may not be tilted, and can be formed perpendicularly to the color filter buffer layer 160. In this example, the holes H can be formed to have directivity in order to further shift the light emitted from the organic light emitting element 130 directed in the front direction in a viewing angle direction. For example, a diameter of the hole H provided in the first region AR1 of each of the color filters 771, 772, 773, and 774 can be 0.1 μm to 1 μm or 0.1 μm to 0.5 μm. In this example, a fine pattern structure is formed in the first region AR1, and the fine pattern structure improves directivity of transmitted light so that the light can be emitted in the viewing angle direction. For example, the holes H provided in the first region AR1 can be arranged in 10 to 20 columns in a direction from outside to inside of the color filters 771, 772, 773, and 774. In addition, each row can include 8 or more, 8 to 100, 8 to 50 or 20 to 50 holes H.

Each of the holes H provided in the first region AR1 is filled with a filler FL. The filler FL further improves the directivity of light. Accordingly, a color viewing angle and a luminance viewing angle of the display device 700 can be further improved. The filler FL can be an anisotropic filler having a refractive index different from that of the color filters 771, 772, 773, and 774. For example, the filler FL can be formed of a material having a refractive index of 1.4 or less or 1.1 to 1.4. For example, the filler FL can be formed of a transparent resin such as acrylic resin, silicone resin, epoxy resin, optically transparent adhesive (OCA), or optically transparent resin. However, the present disclosure is not limited thereto, and a material of the filler FL is not particularly limited, as long as it has a refractive index within the above-mentioned range, and does not degrade display quality.

In the display device 700 according to the example embodiment, the plurality of holes H are provided at the edge of the first region AR1 in a fine pattern structure, and each of the plurality of holes H is filled with the filler FL. Accordingly, light is shifted in the viewing angle direction while passing through the holes H filled with the filler FL, so there are advantages in that the color viewing angle and the luminance viewing angle are excellent or improved.

For convenience of description, a configuration in which the filler fills the hole has been described as an example in the example embodiment, but the present disclosure is not limited thereto. The configuration in which the hole is filled with the filler can also be applied to the display devices illustrated in FIGS. 1 to 15.

Hereinafter, the effects of the present disclosure described above will be described in more detail through Experimental Examples. However, the following Experimental Examples are for exemplification of the present disclosure, and the scope of the present disclosure is not limited by the following Experimental Examples.

### Experimental Examples

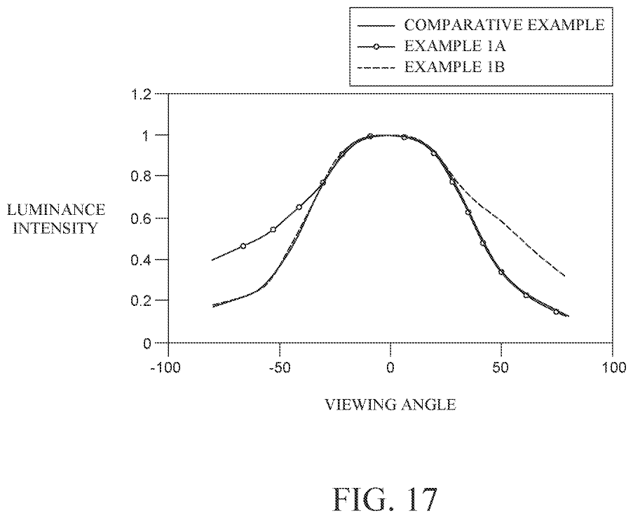

With respect to an example of a color filter unit film, an example where a plurality of holes are formed at a left edge of a color filter unit film to pass through the color filter unit film, and example where a plurality of holes are formed at a right edge of a color filter unit film to pass through the color filter unit film, luminance profiles according to changes in viewing angle were simulated. A simulation result is shown in FIG. 17. In FIG. 17, Comparative Example refers to the color filter unit film, Example 1A refers to a specimen provided with the plurality of holes on the left side of the color filter unit film, and Example 1B refers to a specimen provided with the plurality of holes on the right side of the color filter unit film. In FIG. 17, luminance intensity is a relative ratio of luminance based on front luminance when the front luminance is 1. In FIG. 17, a viewing angle unit is degrees)(°), and a viewing angle is represented by a (−) value in a left direction and a (+) value in a right direction based on the front (0°).

Referring to FIG. 17, it can be seen that Example 1A has a higher luminance than the Comparative Example on a left side thereof, and Example 1B has a higher luminance than the Comparative Example on a right side thereof. For example, when the plurality of holes are provided on the left side of the color filter unit film, the left luminance is improved, and when the plurality of holes are provided on the right side of the color filter unit film, the right luminance is improved. From this, it can be confirmed that when the plurality of holes are formed at the edges of the color filters, luminance viewing angles can be improved.

Hereinafter, color filters of a display device according to various example embodiments of the present disclosure will be discussed with reference to FIGS. 3, 7, 9, 11, 13, 15 and 17. Accordingly, redundant descriptions of the same components will be omitted or may be briefly provided.

A color filter, such as the second color filter 172 can include the plurality of holes H in a body of the color filter 172. Some of the plurality of holes H are full holes formed to penetrate through the body of the color filter 172 and exposes at least a portion of the color filter buffer layer 160, but at least one hole of the plurality of holes H is a partial hole that is formed only partially through the body of the color filter 172 so that the color filter buffer layer 160 is not exposed for that partial hole. The partial hole can extend from the top surface of the second color filter towards the color filter buffer layer 160 but stop before penetrating through the body of the second color filter 172. For example, the partial hole can extend down to a height of the black matrix, but the present disclosure is not limited thereto, and the partial hole can stop before the height of the black matrix, or can further extend past the height of the black matrix. The partial hole can be the middle one that is interposed between adjacent full holes.

In various embodiments of the present disclosure, the partial hole not exposing at least a portion of the color filter buffer layer 160 can be provided, but in other embodiments of the present disclosure, the partial hole can expose at least a portion of the color filter buffer layer 160. For example, the partial hole can be in the middle between adjacent full holes, and exposing the at least a portion of the color filter buffer layer 160, but an upper end of the partial hole can be not opened. Accordingly, the partial hole can extend from the color filter buffer layer 160 but stop before penetrating through the body of the second color filter 172. In various embodiments of the present disclosure, the partial hole that extends from the color filter buffer layer 160 can extend up to a height of the black matrix, but the present disclosure is not limited thereto, and the partial hole can stop before the height of the black matrix, or can further extend past the height of the black matrix.

Some of the plurality of holes H can be full holes that penetrate entirely through the body of the second color filter 172, but two or more of the plurality of holes can be partial holes that do not penetrate through the body of the second color filter 172. When two or more partial holes are present, each of the partial holes can have different lengths. For example, the inner most holes can be full holes while the outer two holes can be partial holes, where the outermost partial hole has a length that is less than the middle partial hole. The locations of the full holes and the partial holes are not limited, and embodiments of the present disclosure includes full holes being the outermost holes, and shortest partial holes being the innermost holes, as well as other combination to provide calibrated improvements in the luminance viewing angle and the color viewing angle of the display device 100, and to suppress the rainbow stain. Thus, in various embodiments of the present disclosure, the hole lengths of the plurality of holes H in a body of the color filter 172 can be different.

Some of the holes H can be filled with a filler FL, which improves the directivity of light to further improve a color viewing angle and a luminance viewing angle of the display device. When a hole H is filled with the filler FL, the entire hole H can be filled with the filler FL or the filler FL can be provided in a portion of the hole H.

The example embodiments of the present disclosure can also be described as follows:

According to an aspect of the present disclosure, a display device comprises a substrate on which a plurality of sub-pixels are defined, an anode disposed on the substrate to correspond to each of the plurality of sub-pixels, an organic light emitting layer disposed on the anode, a cathode disposed on the organic light emitting layer, a bank disposed to cover an edge of the anode to define a plurality of emission areas, an encapsulation layer disposed on the cathode, a black matrix disposed on the encapsulation layer to correspond to the bank and including a plurality of openings overlapping the plurality of emission areas respectively, and a plurality of color filters disposed on the encapsulation layer to correspond to the plurality of sub-pixels respectively, wherein each of the plurality of color filters includes a first region overlapping the emission area and a second region surrounding the first region and having at least a portion disposed to cover at least a portion of an upper surface of the black matrix, and includes a plurality of holes in at least one of an edge of the first region and the second region.

A width of the opening can be equal to each of a width of the first region and a width of the emission area, and the second region can be disposed to be in contact with the upper surface of the black matrix.

The display device can further comprise a color filter buffer layer disposed between the encapsulation layer and the plurality of color filters, wherein the first region can include the plurality of holes at the edge thereof, and the plurality of holes of the first region can expose at least a portion of the color filter buffer layer.

The second region can include the plurality of holes, and the plurality of holes of the second region can expose at least a portion of the black matrix.

The display device can further comprise a color filter buffer layer disposed between the encapsulation layer and the plurality of color filters, wherein each of the first region and the second region can include the plurality of holes, wherein the plurality of holes of the first region can be disposed at the edge adjacent to the black matrix and can expose at least a portion of the color filter buffer layer, and the plurality of holes of the second region can expose at least a portion of the black matrix.

A width of the opening can be greater than a width of the first region, wherein the width of the first region can be equal to a width of the emission area, wherein the second region can include a first sub-region surrounding the first region and in contact with a side surface of the black matrix and a second sub-region surrounding the first sub-region and in contact with the upper surface of the black matrix, and wherein each of the plurality of color filters can include the plurality of holes in at least one of the edge of the first region, the first sub-region, and the second sub-region.

The display device can further comprise a color filter buffer layer disposed between the encapsulation layer and the plurality of color filters, wherein the first region can include the plurality of holes at the edge thereof, and the plurality of holes of the first region can expose at least a portion of the color filter buffer layer.

The display device can further comprise a color filter buffer layer disposed between the encapsulation layer and the plurality of color filters, wherein at least one of the first sub-region and the second sub-region can include the plurality of holes, wherein the plurality of holes of the first sub-region can expose at least a portion of the color filter buffer layer, and the plurality of holes of the second sub-region can expose at least a portion of the black matrix.

Each of the plurality of holes can pass through at least a portion of the color filter in a thickness direction of the color filter from an upper surface of the color filter.

The plurality of holes can be disposed in a plurality of columns from outside to inside of the color filters on a plane.

Each of the plurality of columns can include 8 or more holes.

Each of the plurality of holes can have a circular shape, a polygonal shape, or a line shape on a plane.

Each of the plurality of holes can have a circular shape on a plane, a diameter of each of the plurality of holes can be 0.1 μm to 5 μm, and a distance between the holes adjacent to each other can be 0.1 μm to 5 μm.

Each of the plurality of holes can be tilted from the first region to the second region.

A tilt angle of each of the plurality of holes can be 1° to 25°.

Each of the plurality of holes can be filled with a filler.

The plurality of color filters can be formed of a material having a refractive index of 1.5 or more, and the filler can be formed of a material having a refractive index of 1.4 or less.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate on which a plurality of sub-pixels are defined;
an anode disposed on the substrate to correspond to each of the plurality of sub-pixels;
an organic light emitting layer disposed on the anode;
a cathode disposed on the organic light emitting layer;
a bank covering an edge of the anode to define a plurality of emission areas;
an encapsulation layer disposed on the cathode;
a black matrix disposed on the encapsulation layer to correspond to the bank, and including a plurality of openings overlapping the plurality of emission areas respectively; and
a plurality of color filters disposed on the encapsulation layer to correspond to the plurality of sub-pixels, respectively,
wherein each of the plurality of color filters includes a first region overlapping a corresponding emission area and a second region adjacent the first region and having at least a portion disposed to cover at least a portion of an upper surface of the black matrix, and
wherein at least one of the plurality of color filters includes a plurality of holes in at least one of an edge of the first region and the second region.

2. The display device of claim 1, wherein at least one opening of the plurality of openings corresponds to the first region and the corresponding emission area, and a width of the corresponding opening is approximately equal to a width of the first region and to a width of the corresponding emission area, and
wherein the second region is disposed to be in contact with the upper surface of the black matrix.

3. The display device of claim 2, further comprising:
a color filter buffer layer disposed between the encapsulation layer and the plurality of color filters,
wherein the first region includes the plurality of holes at the edge thereof, and the plurality of holes of the first region expose at least a portion of the color filter buffer layer.

4. The display device of claim 2, wherein the second region includes the plurality of holes, and the plurality of holes of the second region expose at least a portion of the black matrix.

5. The display device of claim 1, wherein a width of a corresponding opening is greater than a width of the first region,
wherein the width of the first region is approximately equal to a width of the corresponding emission area,
wherein the second region includes a first sub-region adjacent the first region and in contact with a side surface of the black matrix, and a second sub-region adjacent the first sub-region and in contact with the upper surface of the black matrix, and
wherein at least one of the plurality of color filters includes the plurality of holes in at least one of the edge of the first region, the first sub-region, and the second sub-region.

6. The display device of claim 5, further comprising:
a color filter buffer layer disposed between the encapsulation layer and the plurality of color filters,
wherein the first region includes the plurality of holes at the edge thereof, and the plurality of holes of the first region expose at least a portion of the color filter buffer layer.

7. The display device of claim 5, further comprising:
a color filter buffer layer disposed between the encapsulation layer and the plurality of color filters,
wherein at least one of the first sub-region and the second sub-region includes the plurality of holes, and
wherein the plurality of holes of the first sub-region expose at least a portion of the color filter buffer layer, and the plurality of holes of the second sub-region expose at least a portion of the black matrix.

8. The display device of claim 1, wherein at least one of the plurality of holes passes through at least a portion of a corresponding color filter in a thickness direction of the corresponding color filter from an upper surface of the corresponding color filter.

9. The display device of claim 1, wherein the plurality of holes are disposed in a plurality of columns from outside to inside of the plurality of color filters on a plane.

10. The display device of claim 1, wherein at least one of the plurality of holes has a circular shape, a polygonal shape, a line shape, or an annular shape on a plane.

11. The display device of claim 1, wherein at least one of the plurality of holes has a circular shape on a plane,
a diameter of the at least one of the plurality of holes is about 0.1 μm to about 5 μm, and
a distance between a pair of the plurality of holes that are adjacent to each other is about 0.1 μm to about 5 μm.

12. The display device of claim 1, wherein at least one of the plurality of holes is tilted from the first region to the second region.

13. The display device of claim 1, wherein at least one of the plurality of holes includes a filler.

14. The display device of claim 13, wherein the plurality of color filters include a material having a refractive index of 1.5 or more, and
wherein the filler includes a material having a refractive index of 1.4 or less.

15. A display device, comprising:
a plurality of sub-pixels defined on a substrate;
a plurality of organic light emitting elements disposed to correspond to the plurality of sub-pixels, respectively, and having a plurality of emission areas, respectively;
banks to define the plurality of emission areas corresponding to the plurality of sub-pixels;
an encapsulation layer disposed on the plurality of organic light emitting elements;
a black matrix disposed on the encapsulation layer to correspond to the banks, and including a plurality of openings corresponding to the plurality of emission areas, respectively; and
a plurality of color filters disposed on the encapsulation layer to correspond to the plurality of sub-pixels, respectively,
wherein each of the plurality of color filters includes a plurality of holes grouped into an inner pattern and an outer pattern having different sizes.

16. The display device of claim 15, wherein a size of the inner pattern is less than a size of the outer pattern.

17. The display device of claim 15, wherein each of the inner pattern and the outer pattern is an annular pattern.

18. The display device of claim 15, wherein at least one of the inner pattern and the outer pattern includes a circular shape, a polygonal shape, a line shape, or an annular shape on a plane.

19. The display device of claim 1, wherein some of the plurality of holes are partial holes that partially penetrate a corresponding color filter of the plurality of color filters.

20. A display device, comprising:
a plurality of sub-pixels defined on a substrate;
a plurality of organic light emitting elements disposed to correspond to the plurality of sub-pixels, respectively, and having a plurality of emission areas, respectively;
an encapsulation layer disposed on the plurality of organic light emitting elements; and
a plurality of color filters disposed on the encapsulation layer to correspond to the plurality of sub-pixels, respectively,
wherein each of the plurality of color filters includes a first part, a second part that is outward of the first part, and a third part that is outward of the second part, and
wherein a plurality of holes are included in the second part and encircle the first part.
